(19) United States
(12) Patent Application Publication
(10) Pub. No.: US 2026/0198205 A1
(43) Pub. Date: Jul. 9, 2026

(54) Display Device

(71) Applicant: LG Display Co., Ltd., Seoul (KR)

(72) Inventor: Kyoung-Hoon Kim, Paju-si (KR)

(21) Appl. No.: 19/370,392

(22) Filed: Oct. 27, 2025

(30) Foreign Application Priority Data
Dec. 12, 2024 (KR) 10-2024-0184480

(51) Int. Cl. H10K 59/80; H10K 59/131

(52) U.S. Cl. CPC H10K 59/8722; H10K 59/131; H10K 59/8793

(57) ABSTRACT

A display device includes a display panel, a back plate disposed below the display panel, a printed circuit board disposed below the back plate and electrically connected to the display panel, a chip on film having a first side electrically connected to the display panel and a second side electrically connected to the printed circuit board, and a first adhesive layer including a first region disposed between the display panel and the back plate, a second region extending from the first region and bent to surround one end of the back plate, and a third region extending from the second region and disposed between the back plate and the printed circuit board and between the chip on film and the back plate.

### CROSS REFERENCE TO RELATED APPLICATIONS

The present application claims the priority benefit of Republic of Korea Patent Application No. 10-2024-0184480 filed in Republic of Korea on Dec. 12, 2024, which is hereby incorporated by reference in its entirety.

### FIELD OF THE INVENTION

The present disclosure relates to a display device, and more specifically, to a display device capable of reducing a thickness of the display device and preventing damage to a driving element mounted on a chip on film.

### BACKGROUND

The contents described in this section merely provides background information on the present invention and does not constitute prior art.

With the advent of a full-fledged information age, a field of display devices, which visually display electrical information signals, is rapidly evolving, and research is ongoing to develop performances such as thinning, weight reduction, and low power consumption for various display devices.

Such display devices include liquid crystal display devices (LCDs), quantum dot display panel devices (QDs), field emission display devices (FEDs), electro-wetting display devices (EWDs), and organic light emitting display devices (OLEDs).

The display devices are being developed to be miniaturized and portable, or to be installed in mobile devices such as vehicles, so that the display devices are being improved to provide greater user convenience.

The display devices can include a chip on film (COF) that electrically connects a display panel to a printed circuit board. In order to slim down the display devices and prevent damage to a driving element mounted on the chip on film, the display panel and the chip on film need to be firmly fixed to each other.

### SUMMARY

An advantage of the present disclosure is to provide a display device with reduced thickness.

Another advantage of the present disclosure is to provide a display device capable of suppressing or preventing damage to a driving element mounted on a chip on film.

Another advantage of the present disclosure is to provide a display device capable of improving structural stability of a chip on film and a display panel.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes a display panel, a back plate disposed below the display panel, a printed circuit board disposed below the back plate and electrically connected to the display panel, a chip on film having a first side electrically connected to the display panel and a second side electrically connected to the printed circuit board, and a first adhesive layer including a first region disposed between the display panel and the back plate, a second region extending from the first region and bent to surround one end of the back plate, and a third region extending from the second region and disposed between the back plate and the printed circuit board and between the chip on film and the back plate.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is an exploded perspective view of a display device according to an embodiment of the present disclosure;

FIG. 2 is a rear view of a display device with a chip on film of FIG. 1 bent;

FIG. 3 is a perspective view of a first adhesive layer and a back plate of FIG. 1;

FIG. 4 is a cross-sectional view taken along a line I-I′ of FIG. 2; and

FIG. 5 is a cross-sectional view of three subpixels of the display panel of FIG. 1.

### DETAILED DESCRIPTION OF THE ILLUSTRATED EMBODIMENTS

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure.

The shapes, areas, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising’, ‘including’, ‘having’, ‘consisting’, and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

When an element or layer is referred to as being ‘on’ another element or layer, it includes cases where a third element or layer is directly on the other element or layer or is interposed therebetween.

In describing components of the present disclosure, terms such as first, second and the like can be used. These terms are only for distinguishing the components from other components, and an essence, order, sequence, or number of the components is not limited by the terms.

Throughout the present disclosure, the same reference numerals designate the same components.

The area and thickness of each component shown in the drawings are illustrated for convenience of explanation, and the present disclosure is not necessarily limited to the area and thickness of the component shown.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings.

A display device according to an embodiment of the present disclosure can be installed, for example, in front of a front seat of a vehicle, to provide a driver and a passenger with images or video necessary for driving. However, the present disclosure is not limited thereto, and the display device can be carried and used by a user without being installed in the vehicle. Hereinafter, for example, a display device installed in a vehicle can be described.

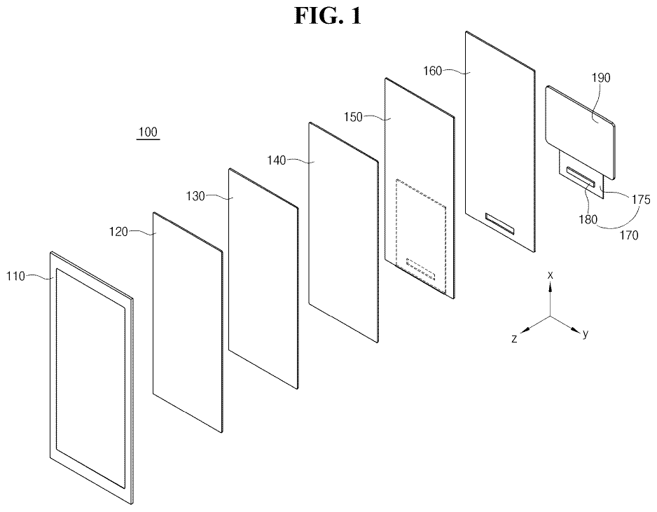

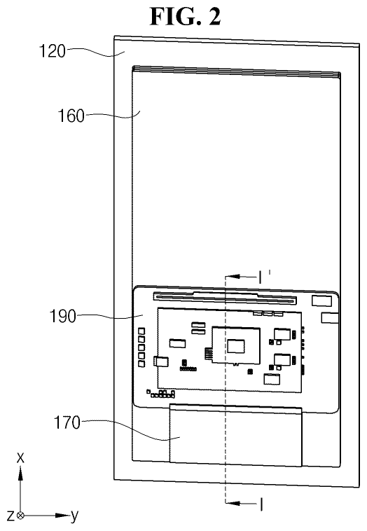

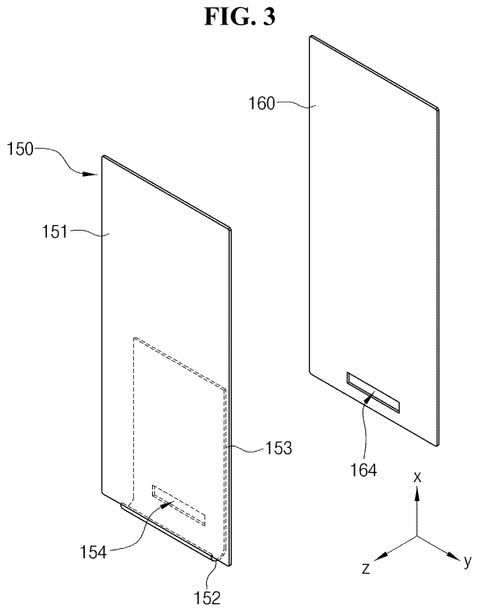

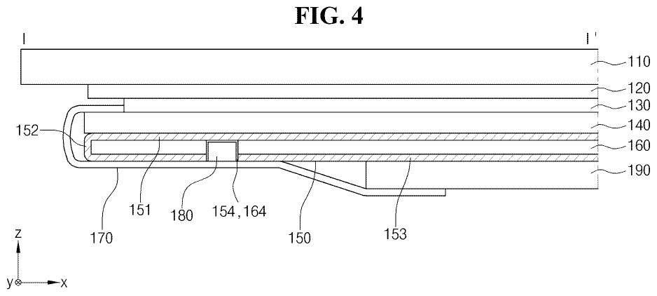

FIG. 1 is an exploded perspective view of a display device according to an embodiment of the present disclosure. FIG. 2 is a rear view of a display device with a chip on film of FIG. 1 bent. FIG. 3 is a perspective view of a first adhesive layer and a back plate of FIG. 1. FIG. 4 is a cross-sectional view taken along a line I-I′ of FIG. 2.

The display device 100 according to an embodiment of the present disclosure can include an electroluminescent display device. The electroluminescent display device can include an organic light emitting diode display device, a quantum dot light emitting diode display device, or an inorganic light emitting diode display device.

Meanwhile, the display device 100 according to an embodiment of the present disclosure can be a device that includes both a display function for displaying an image and a touch sensing function for sensing a user's touch, but not limited thereto. For example, the display device 100 can include one of the display function for displaying an image and the touch sensing function for sensing the user's touch.

In embodiments of the present disclosure, a first direction x and a second direction y can be different directions and intersect each other, for example, directions that intersect perpendicularly in a plan view. In FIG. 1, the first direction x can represent a left-right direction in a plan view, and the second direction y can represent an up-down direction in a plan view. A third direction z can represent an up-down direction in a cross-sectional view. However, it should be understood that the directions mentioned in the embodiments refer to relative directions, and the embodiments are not limited to the mentioned directions.

Referring to FIGS. 1 to 4, the display device 100 can include a display panel 140, a first adhesive layer 150 disposed below the display panel 140, a back plate 160 disposed below the first adhesive layer 150, a printed circuit board 190 disposed below the back plate 160, a chip on film COF 170 electrically connected to the display panel 140 and the printed circuit board 190, a polarizing layer 130 disposed on the display panel 140, a second adhesive layer 120 disposed on the polarizing layer 130, and a cover layer 110 disposed on the second adhesive layer 120.

The display panel 140 can display an image or video. The displayed image or video can include a navigation information required for driving, an image captured by a camera mounted on the vehicle, or other various content required by the driver or passenger.

The back plate 160 can be positioned below the display panel 140. The back plate 160 can be formed in a thin shape to produce a slim display device 100. The back plate 160 can protect the display panel 140, and serve as a heat sink that dissipates heat generated from the display panel 140 to the outside and cools the display panel 140.

The back plate 160 can be formed of, for example, aluminum, an alloy containing aluminum, copper, or an alloy containing copper. However, the present disclosure is not limited thereto.

The printed circuit board 190 can be positioned below the back plate 160 and electrically connected to the display panel 140 via the chip on film 170. Various components can be positioned on the printed circuit board 190 to supply various signals, such as gate control signals, driving signals, and data signals, to the driving element 180 of the chip on film 170.

A first side of the chip on film 170 can be electrically connected to the display panel 140, and a second side of the chip on film 170 can be electrically connected to the printed circuit board 190. The chip on film 170 can be attached to a non-display region of the display panel 140 and can be attached to a bottom of the printed circuit board 190. A portion of the chip on film 170 can be bent to surround one end of the display panel 140 and the back plate 160.

The chip on film 170 can be electrically connected to a pad portion of the display panel 140. Accordingly, the chip on film 170 can supply gate control signals, driving signals, power voltages, data voltages, etc. to a plurality of pixels and a gate driving portion arranged in the display panel 140.

The chip on film 170 can be formed in a thin shape and made of a flexible material to enable bending. The chip on film 170 can include a flexible film 175 having a printed circuit formed therein, and the driving element 180 mounted on the flexible film 175 and driving the display panel 140.

The flexible film 175 can be a flexible insulating film. The flexible film 175 can include, for example, but not limited to, polycarbonate, polyethylene terephthalate, polyimide, polyamide, polyester, polyacrylate, polymethyl methacrylate, or the like.

The driving element 180 can be configured with an integrated circuit (IC) that controls operation of the display device 100. The driving element 180 can process data signals for displaying an image and various driving signals for processing the data signals. The driving element 180 can include a gate driver IC, a data driver IC, and the like. The driving element 180 can be mounted on the flexible film 175, and can protrude from the flexible film 175.

The first adhesive layer 150 can be positioned between the display panel 140 and the back plate 160 and can adhere the display panel 140 and the back plate 160 to each other.

The first adhesive layer 150 can be configured in a form of a film or plate, and can be formed of an adhesive material. The first adhesive layer 150 can be formed of a transparent material with high light transmittance.

The first adhesive layer 150 can be formed of or include a material with good adhesive strength, for example, but not limited to, an optical clear adhesive (OCA), an optical clear resin (OCR), or a pressure sensitive adhesive (PSA).

The first adhesive layer 150 can be formed of a transparent material. However, the present disclosure is not limited thereto, and the first adhesive layer 150 disposed between the display panel 140 and the back plate 160 can be formed of a non-transparent adhesive.

When the first adhesive layer 150 includes the pressure sensitive adhesive (PSA), the first adhesive layer 150 can be a double-sided adhesive.

The polarizing layer 130 can be disposed on the display panel 140. The polarizing layer 130 can polarize light emitted from the display panel 140 at a polarization angle. The polarizing layer 130 can emit light polarized at the polarization angle to the outside. The polarizing layer 130 can have a function of blocking reflection of light, except for light polarized at the polarization angle, among an external light. The polarizing layer 130 can include a first phase retardation layer, a second phase retardation layer on the first phase retardation layer, and a polarization layer on the second phase retardation layer. However, embodiments of the present disclosure are not limited thereto. In FIG. 1, the polarizing layer 130 and the display panel 140 are illustrated as being separate from each other, but not limited thereto. The polarizing layer 130 can be included in the display panel 140.

The cover layer 110 can be disposed on the polarizing layer 130. The cover layer 110 can be disposed over the display panel 140 to protect the display panel 140. The cover layer 110 can be formed of a transparent material, so that light irradiated onto the cover layer 110 can pass through the cover layer 110.

The cover layer 110 can be made of, for example, transparent glass or a transparent plastic material, but not limited thereto. The cover layer 110 can be formed by chemical strengthening.

The cover layer 110 can be formed relatively thick to protect other components therebelow and maintain rigidity of the entire display device 100, thereby preventing the display device 100 from being easily deformed by external impact. To enhance durability of the cover layer 110, the display device 100 can further include at least one other layer on the cover layer 110.

The second adhesive layer 120 can be positioned between the cover layer 110 and the polarizing layer 130, and can adhere the cover layer 110 and the polarizing layer 130 to each other. The second adhesive layer 120 can be formed of the same or similar material as the first adhesive layer 150.

The first adhesive layer 150 can include a first region 151 positioned between the display panel 140 and the back plate 160, a second region 152 extending from the first region 151 and being bent to surround one end of the back plate 160, and a third region 153 extending from the second region 152 and positioned between the back plate 160 and the printed circuit board 190. The third region 153 can also be positioned between the chip on film 170 and the back plate 160.

The first adhesive layer 150 can be in direct contact with the back plate 160, and can also be in direct contact with the chip on film 170 and the printed circuit board 190.

The first region 151 can be formed to overlap an entire region of the back plate 160. Lengths of the second region 152 and the third region 153 in the second direction y can be equal to or smaller than a length of the chip on film 170 in the second direction y. A side surface of the third region 153 can be positioned inward relative to a side surface of the printed circuit board 190.

Meanwhile, the first adhesive layer 150 can include an opening 154 corresponding to a region of the driving element 180. The opening 154 can be formed in the third region 153 of the first adhesive layer 150. When the chip on film 170 is bent in a thickness direction (i.e., the third direction z) of the display device 100, the driving element 180 can be inserted into the opening 154 of the first adhesive layer 150.

The back plate 160 can also include a groove (or hole) 164 corresponding to the region of the driving element 180. When the chip on film 170 is bent in the thickness direction (i.e., the third direction z) of the display device 100, the driving element 180 can be inserted into the groove 164 of the back plate 160. When the driving element 180 is inserted into the groove 164 of the back plate 160, the driving element 180 can face the display panel 140. The groove 164 can be formed in a form of a through hole, depending on the thickness of the back plate 160.

The chip on film 170 can be equipped with the driving element 180 that drives the display device 100. The chip on film 170 can be formed of a thin, flexible material. Therefore, the chip on film 170 can be highly effective in increasing assembly convenience and reducing a space occupied by components.

The chip on film 170 can electrically connect the display panel 140 and the printed circuit board 190. To this end, the chip on film 170 can be bent and positioned adjacent to an edge of the display panel 140. Accordingly, the chip on film 170 can protrude from a bottom of the display panel 140.

To minimize the thickness of the display device 100, a height of a bending portion of the chip on film 170 needs to be minimized. To do this, it can be necessary to minimize a length of the chip on film 170 or change a position of the printed circuit board 190. However, minimizing the length of the chip on film 170 increases a risk of damage to the chip on film 170, and changing the position of the printed circuit board 190 limits design changes to a set of the display device 100.

Meanwhile, the display device 100 can be subject to external impact during use. For example, when the display device 100 is mounted on a movable device such as a vehicle, external impacts from the vehicle's movement may be transmitted to the display device 100.

When the display device 100 is subject to the external impact, some components of the display device 100 may be damaged by the external impact, resulting in malfunction or failure of the display device 100.

In particular, when the display device 100 has a slim structure or includes flexible components that can be bent, an influence of the external impact may be even greater.

Since the chip on film 170 is manufactured in a thin form, it may be vulnerable to the external impact. Such that external impact may cause the chip on film 170 to be damaged. Therefore, development of a technology capable of preventing damage to the chip on film 170 due to the external impact is required.

In particular, the driving element 180 provided in the chip on film 170 has a predetermined volume and may be provided to protrude from the chip on film 170. Therefore, when the external impact is applied to the chip on film 170, the flexible chip on film 170 easily moves, and accordingly, the driving element 180 provided in the chip on film 170 may also move.

The driving element 180 is prone to damage by moving and colliding with other components of the display device 100. The damage to the driving element 180 can have a serious influence on the entire display device 100. Therefore, development of a structure that protects the driving element 180 from the external impact is required.

In the display device 100 according to an embodiment of the present disclosure, the second region 152 and the third region 153 which extend from the first region 151 of the first adhesive layer 150 can be arranged between the back plate 160 and the chip on film 170 to adhere the back plate 160 and the chip on film 170 to each other. Accordingly, the height of the bending portion of the chip on film 170 can be reduced, and by fixing the chip on film 170 to the back plate 160, the damage to the driving element 180 on the chip on film 170 due to the external impact can be prevented.

Furthermore, the driving element 180 mounted on the chip on film 170 can be inserted into the opening 154 of the first adhesive layer 150 and the groove 164 of the back plate 160. Accordingly, the height of the bending portion of the chip on film 170 can be reduced, and the driving element 180 mounted on the chip on film 170 can be protected by the groove 164 of the back plate 160, so that the damage to the driving element 180 on the chip on film 170 due to the external impact can be prevented.

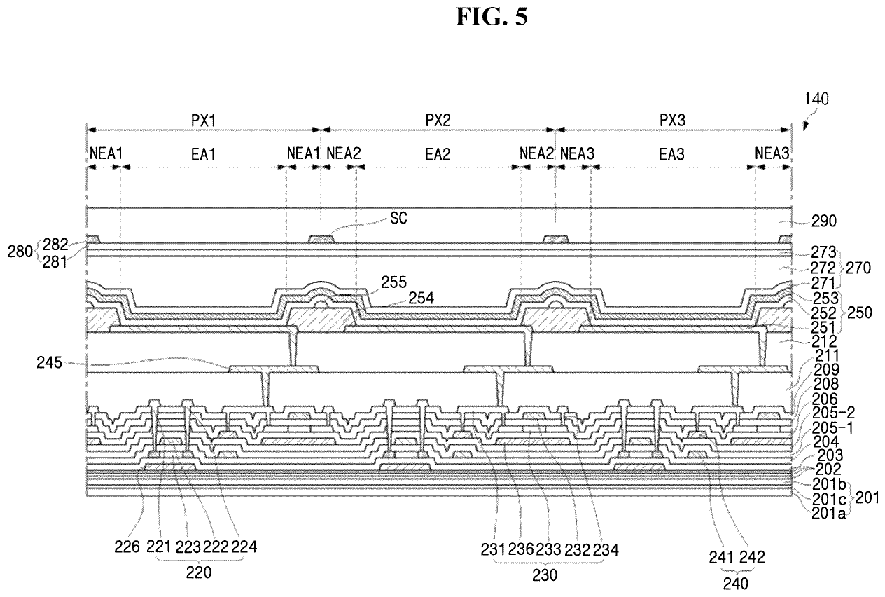

FIG. 5 is a cross-sectional view of three subpixels of the display panel of FIG. 1.

Referring to FIG. 5, a pixel of the display panel 140 can include a plurality of subpixels PX1, PX2, and PX3. The first sub-pixel PX1 can be a red subpixel, the second subpixel PX2 can be a green subpixel, and the third subpixel PX3 can be a blue subpixel, but embodiments of the present disclosure are not limited thereto. In some embodiments, the pixel can further include a fourth subpixel, and the fourth subpixel can be a white subpixel, but embodiments of the present disclosure are not limited thereto.

The display panel 140 can include a substrate 201, a first thin film transistor 220, a second thin film transistor 230, a light emitting portion 250, an encapsulation portion 270, and a touch portion 280. The display panel 140 can include at least one panel insulating layer between the substrate 201 and the light emitting portion 250, and at least one touch insulating layer. The at least one panel insulating layer can include at least one of a buffer layer 202, a first insulating layer 203, a second insulating layer 204, a third insulating layer 205-1 and 205-2, a fourth insulating layer 206, a fifth insulating layer 208, a sixth insulating layer 209, a first passivation layer 211, and a second passivation layer 212, which are described later, and the at least one touch insulating layer can include a touch buffer layer 281. The third insulating layer 205-1 and 205-2 can include a third, first insulating layer 205-1, and a third, second insulating layer 205-2.

The substrate 201 can include one or more plastic materials. For example, the substrate 201 can be a multi-substrate including multiple plastic materials, such as polyimide. For example, the substrate 201 can include a first substrate portion 201a and a second substrate portion 201b, which each include a plastic material, and a third substrate portion 201c which includes an inorganic insulating material between the first substrate portion 201a and the second substrate portion 201b, but embodiments of the present disclosure are not limited thereto.

The buffer layer 202 can be disposed on the substrate 201. The buffer layer 202 can minimize or delay diffusion of moisture or oxygen penetrating the substrate 201. The buffer layer 202 can be formed by alternately stacking silicon nitride (SiNx) and silicon oxide (SiOx) at least once, but embodiments of the present disclosure are not limited thereto.

A first light-blocking layer 226 can be disposed on the buffer layer 202. The first light-blocking layer 226 can prevent light from being transmitted to a first semiconductor layer 223 of the first thin film transistor 220. For example, the first semiconductor layer 223 can be disposed to overlap the first light-blocking layer 226. The first light-blocking layer 226 can be configured in a single layer or multiple layers using at least one of molybdenum (Mo), aluminum (Al), chromium (Cr), nickel (Ni), neodymium (Nd), copper (Cu), and an alloy thereof, but embodiments of the present disclosure are not limited thereto.

The first insulating layer 203 can be disposed on the buffer layer 202 and the first light-blocking layer 226. The first insulating layer 203 can prevent a short circuit between the first thin film transistor 220 and the first light-blocking layer 226. The first insulating layer 203 can be made of the same material as the buffer layer 202, but embodiments of the present disclosure are not limited thereto. For example, the first insulating layer 203 can be made of an inorganic insulating material such as silicon nitride (SiNx) or silicon oxide (SiOx), but embodiments of the present disclosure are not limited thereto.

The first thin film transistor 220 can be disposed on the first insulating layer 203. The first thin film transistor 220 can include a first source electrode 221, a first gate electrode 222, a first semiconductor layer 223, and a first drain electrode 224.

The first semiconductor layer 223 can be disposed on the first insulating layer 203. The first semiconductor layer 223 can include a metal oxide semiconductor, such as Indium-Gallium-Zinc Oxide (IGZO), or a silicon-based semiconductor material, such as amorphous silicon or polycrystalline silicon, but embodiments of the present disclosure are not limited thereto. The first semiconductor layer 223 can include a channel region, a source region, and a drain region.

Since a polycrystalline semiconductor layer has higher mobility than an amorphous semiconductor layer and an oxide semiconductor layer, it can have lower power consumption and superior reliability. Accordingly, a driving transistor can be formed with the polycrystalline semiconductor layer.

The second insulating layer 204 can be disposed on the first semiconductor layer 223. The second insulating layer 204 can be made of the same material as the first insulating layer 203, and can prevent a short circuit between the first semiconductor layer 223 and other components of the first thin film transistor 220.

The first gate electrode 222 can be disposed on the second insulating layer 204. The first gate electrode 222 can be disposed on the second insulating layer 204 so as to overlap the channel region of the first semiconductor layer 223. The first gate electrode 222 can be configured in a single layer or multiple layers using at least one of molybdenum (Mo), copper (Cu), titanium (Ti), aluminum (Al), chromium (Cr), gold (Au), nickel (Ni), neodymium (Nd), and a compound thereof, but embodiments of the present disclosure are not limited thereto. The first gate electrode 222 can be arranged together with a gate line.

The third insulating layer 205-1 and 205-2 can be disposed on the first gate electrode 222. The third insulating layer 205-1 and 205-2 can be formed by alternately stacking silicon nitride (SiNx) and silicon oxide (SiOx) at least once, but embodiments of the present disclosure are not limited thereto. For example, the third, first insulating layer 205-1 can include silicon oxide (SiOx), and the third, second insulating layer 205-2 can include silicon nitride (SiNx), but embodiments of the present disclosure are not limited thereto.

The first source electrode 221 and the first drain electrode 224 can be disposed on the third insulating layer 205-1 and 205-2.

The first source electrode 221 and the first drain electrode 224 can be electrically connected to the first semiconductor layer 223 through contact holes. The first source electrode 221 and the first drain electrode 224 can be formed of a metal material. For example, the first source electrode 221 and the first drain electrode 224 can be formed in a single layer or multiple layers using at least one of molybdenum (Mo), aluminum (Al), chromium (Cr), gold (Au), titanium (Ti), nickel (Ni), neodymium (Nd), copper (Cu), and an alloy thereof, but embodiments of the present disclosure are not limited thereto.

The first source electrode 221 and the first drain electrode 224 can be arranged together with a data line. For example, the data line can be formed at the same layer as and of the same material as the first source electrode 221 and the first drain electrode 224, but embodiments of the present disclosure are not limited thereto.

Storage electrodes 240 can be disposed spaced apart from the first thin film transistor 220. The storage electrodes 240 can include a first storage electrode 241 and a second storage electrode 242.

The first storage electrode 241 can be disposed at the same layer as and of the same material as the first gate electrode 222, but embodiments of the present disclosure are not limited thereto.

The second storage electrode 242 can be disposed on the first storage electrode 241. The second storage electrode 242 can be disposed on the third insulating layer 205-1 and 205-2, and a capacitance can be formed by using the third insulating layer 205-1 and 205-2 between the first storage electrode 241 and the second storage electrode 242 as a dielectric. The second storage electrode 242 can be made of the same material as the first storage electrode 241, but embodiments of the present disclosure are not limited thereto.

A second thin film transistor 230 can be disposed spaced apart from the first thin film transistor 220 and the storage electrode 240. The second thin film transistor 230 can include a second source electrode 231, a second gate electrode 232, a second semiconductor layer 233, and a second drain electrode 234.

A second light-blocking layer 236 can be disposed at the same layer as the second storage electrode 242.

Similar to the first light-blocking layer 226, the second light-blocking layer 236 can block light from reaching the second semiconductor layer 233, thereby extending a lifespan of the second thin film transistor 230. For example, the second semiconductor layer 233 can be disposed overlapping the second light-blocking layer 236.

The fourth insulating layer 206 can be disposed on the second light-blocking layer 236. The fourth insulating layer 206 can be made of the same material as the first insulating layer 203, the second insulating layer 204, or the third insulating layer 205-1 and 205-2, but embodiments of the present disclosure are not limited thereto.

The second semiconductor layer 233 can be disposed on the fourth insulating layer 206. The second semiconductor layer 233 can include a source region, a drain region, and a channel region between the source and drain regions.

The second semiconductor layer 233 can include a metal oxide semiconductor, such as Indium-Gallium-Zinc Oxide (IGZO), or a silicon-based semiconductor material, such as amorphous silicon or polycrystalline silicon, but embodiments of the present disclosure are not limited thereto.

The fifth insulating layer 208 can be disposed on the second semiconductor layer 233. The fifth insulating layer 208 can be made of the same material as the first insulating layer 203, the second insulating layer 204, the third insulating layer 205-1 and 205-2, or the fourth insulating layer 206, but embodiments of the present disclosure are not limited thereto.

The second gate electrode 232 can be disposed on the fifth insulating layer 208.

The second gate electrode 232 can be made of the same material as the first gate electrode 222. For example, the second gate electrode 232 can be formed in a single layer or multiple layers using at least one of molybdenum (Mo), copper (Cu), titanium (Ti), aluminum (Al), chromium (Cr), gold (Au), nickel (Ni), neodymium (Nd), and a compound thereof, but embodiments of the present disclosure are not limited thereto.

The sixth insulating layer 209 can be disposed on the second gate electrode 232. The sixth insulating layer 209 can be made of the same material as the first insulating layer 203, the second insulating layer 204, the third insulating layer 205-1 and 205-2, the fourth insulating layer 206, or the fifth insulating layer 208, but embodiments of the present disclosure are not limited thereto.

The first source electrode 221, the first drain electrode 224, the second source electrode 231, and the second drain electrode 234 can be disposed on the sixth insulating layer 209.

The second source electrode 231 and the second drain electrode 234 can be formed of the same material as and at the same layer as the first source electrode 221 and the first drain electrode 224, but embodiments of the present disclosure are not limited thereto. For example, the second source electrode 231 and the second drain electrode 234 can be formed in a single layer or multiple layers using at least one of molybdenum (Mo), aluminum (Al), chromium (Cr), gold (Au), titanium (Ti), nickel (Ni), neodymium (Nd), copper (Cu), and an alloy thereof, but embodiments of the present disclosure are not limited thereto. For example, the second source electrode 231 can be electrically connected to the second storage electrode 242. The second source electrode 231 can be electrically connected to the second storage electrode 242 by penetrating the sixth insulating layer 209, the fifth insulating layer 208, and the fourth insulating layer 206.

The first thin film transistor 220 can be a driving transistor, and the second thin film transistor 230 can be a switching transistor, but embodiments of the present disclosure are not limited thereto.

The first passivation layer 211 can be disposed on the first source electrode 221 and the first drain electrode 224.

The first passivation layer 211 can planarize the substrate 201 having the first thin film transistor 220 and protect the first thin film transistor 220. The first passivation layer 211 can be made of an organic material. For example, the first passivation layer 211 can be formed of an organic material, such as acrylic resin, epoxy resin, phenolic resin, polyamide resin, or polyimide resin, but embodiments of the present disclosure are not limited thereto.

The second passivation layer 212 can be formed on the first passivation layer 211. The second passivation layer 212 can be formed of the same material as the first passivation layer 211, but embodiments of the present disclosure are not limited thereto.

In some embodiments, a third passivation layer can be further formed on the second passivation layer 212, but embodiments of the present disclosure are not limited thereto.

A connection electrode 245 can be formed between the first passivation layer 211 and the second passivation layer 212.

The connection electrode 245 can electrically connect the second thin film transistor 230 and the light emitting portion 250. The connection electrode 245 can be made of the same material as the first source electrode 221 and the first drain electrode 224, but embodiments of the present disclosure are not limited thereto.

The connection electrode 245 can be formed in a single layer or multiple layers using molybdenum (Mo), aluminum (Al), chromium (Cr), gold (Au), titanium (Ti), nickel (Ni), neodymium (Nd), and copper (Cu), and an alloy thereof, but embodiments of the present disclosure are not limited thereto.

The light emitting portion 250 can be disposed on the second passivation layer 212. The light emitting portion 250 can include an anode electrode 251, an organic layer 252, and a cathode electrode 253.

The anode electrode 251 can be disposed on the second passivation layer 212. The anode electrode 251 can be electrically connected to the second thin film transistor 230 through a contact hole formed in the second passivation layer 212. The anode electrode 251 can be a reflective electrode that reflects light, but embodiments of the present disclosure are not limited thereto. The anode electrode 251 can include a highly reflective metal material such as a laminated structure of aluminum (Al) and titanium (Ti) (e.g., Ti/Al/Ti), a laminated structure of aluminum (Al) and indium tin oxide (ITO) (e.g., ITO/Al/ITO), or an APC alloy, and can be formed in a single layer or multiple layers, but embodiments of the present disclosure are not limited thereto.

The organic layer 252 can be disposed on the anode electrode 251. The organic layer 252 can include one or more light emitting structures (or light emitting elements) laminated on the anode electrode 251 in the order of a hole transport layer and an electron transport layer or in the reverse order. For example, the hole transport layer can include a hole transport layer, a hole injection layer, an electron blocking layer, or a P-type charge generation layer, but embodiments of the present disclosure are not limited thereto. For example, the electron transport layer can include an electron transport layer, an electron injection layer, a hole blocking layer, or an N-type charge generation layer, but embodiments of the present disclosure are not limited thereto. The organic layer 252 can be an organic light emitting layer, an inorganic light emitting layer, a quantum dot light emitting layer, a micro light emitting diode, or a micro mini light emitting diode, but embodiments of the present disclosure are not limited thereto. For example, the organic layer 252 of the display panel 140 according to an embodiment of the present disclosure can include an organic light emitting layer. The organic layer 252 can include a red light emitting layer, a green light emitting layer, and a blue light emitting layer. The organic layer 252 can further include a white light emitting layer, but embodiments of the present disclosure are not limited thereto.

The cathode electrode 253 can be disposed on the organic layer 252. The cathode electrode 253 can be a transparent electrode that transmits light, but embodiments of the present disclosure are not limited thereto. For example, the cathode electrode 253 can include a transparent conductive material such as ITO (Indium Tin Oxide) or IZO (Indium Zinc Oxide), or a metal that transmits visible light, but embodiments of the present disclosure are not limited thereto.

A bank 254 can be disposed to expose the anode electrode 251. The bank 254 can define openings (or an emission regions EA1, EA2 and EA3) of the subpixels PX1, PX2, and PX3 and can be disposed to cover an edge portion (or a border portion, or a peripheral portion) of the anode electrode 251. In other words, the first subpixel PX1 can include a first emission region EA1 and a first non-emission region NEA1 around the first emission region EA1, the second subpixel PX2 can include a second emission region EA2 and a second non-emission region NEA2 around the second emission region EA2, and the third subpixel PX3 can include a third emission region EA3 and a third non-emission region NEA3 around the third emission region EA3. In other words, each of the non-emission regions NEA1, NEA2, and NEA3 can correspond to a boundary between adjacent subpixels PX1, PX2, and PX3.

The bank 254 can be made of an organic insulating material such as benzocyclobutene (BCB), polyimide, and photo acryl. However, the present disclosure is not limited thereto, and the bank 254 can include a black material. For example, the bank 254 can be formed of a material including a black pigment or the like, or an organic material such as a benzocyclobutene resin, a polyimide resin, an acryl resin, or a photosensitive polymer. In this case, when the bank 254 is formed of a material including a black pigment or a black dye, it can be a black bank. When the bank 254 is formed of a material including a black pigment or a black dye, it can block light from the outside or light reflected from the outside, thereby further improving a brightness of the display device 100.

A spacer 255 can be further disposed on the bank 254. The spacer 255 can be formed of the same material as the bank 254, but embodiments of the present disclosure are not limited thereto. For example, the spacer 255 can be a transparent bank, but not limited thereto, and it can be formed of the same material as the bank 254. For example, the spacer 255 can be disposed on at least one of the boundaries between the first to third subpixels PX1 to PX3, but embodiments of the present disclosure are not limited thereto. In some embodiments, the bank 254 and the spacer 255 can be formed of the same material and can be simultaneously formed through a halftone mask, but embodiments of the present disclosure are not limited thereto.

The organic layer 252 can be disposed on the anode electrode 251, the bank 254, and the spacer 255. The cathode electrode 253 can be disposed on the organic layer 252.

The encapsulation portion 270 can be disposed on the cathode electrode 253. The encapsulation portion 270 can include one or more insulating layers. For example, the encapsulation portion 270 can include a first encapsulation layer 271, a second encapsulation layer 272 disposed on the first encapsulation layer 271, and a third encapsulation layer 273 disposed on the second encapsulation layer 272. The encapsulation portion 270 can include one or more inorganic insulating material layers and one or more organic material layers. For example, the first encapsulation layer 271 and the third encapsulation layer 273 can include an inorganic insulating material, and the second encapsulation layer 272 can include an organic material, but embodiments of the present disclosure are not limited thereto.

The touch portion 280 can be disposed on the encapsulation portion 270. The touch portion 280 can include a touch buffer layer 281, a first touch conductive layer 282, and a touch organic layer 290.

The touch buffer layer 281 can be disposed on the third encapsulation layer 273. The touch buffer layer 281 can be made of the same material as the buffer layer 202, but embodiments of the present disclosure are not limited thereto.

The first touch conductive layer 282 can be disposed on the touch buffer layer 281. The first touch conductive layer 282 can include a sensor electrode SC. The sensor electrode SC can be disposed in the non-emission regions NEA1, NEA2, and NEA3 and may not be disposed in the emission regions EA1, EA2, and EA3. The sensor electrode SC can be positioned at the boundaries between adjacent subpixels PX1, PX2, and PX3.

The first touch conductive layer 282 can include a metal material. For example, the first touch conductive layer 282 can be made of titanium (Ti), nickel (Ni), aluminum (Al), or an alloy thereof, and can be formed with three layers such as titanium (Ti)/aluminum (Al)/titanium (Ti), but embodiments of the present disclosure are not limited thereto.

The touch organic layer 290 can be disposed on the first touch conductive layer 282. The touch organic layer 290 can include an organic insulating material, but embodiments of the present disclosure are not limited thereto.

However, the touch portion 280 is not limited to the above configuration, and the touch portion 280 can include two or more touch conductive layers. For example, the touch portion 280 can include a buffer layer, a bridge electrode disposed on the buffer layer, a touch insulating layer disposed on the bridge electrode, a touch conductive layer disposed on the touch insulating layer, and a touch organic layer disposed on the touch conductive layer.

A polarizing film and/or a color filter can be disposed on the touch portion 280, but embodiments of the present disclosure are not limited thereto.

According to the embodiments of the present disclosure, by extending the adhesive layer that bonds the display panel and the back plate together and bonding the chip on film and the printed circuit board to the back plate, the thickness of the display device can be reduced and the structural stability of the display device can be improved.

According to the embodiments of the present disclosure, by providing the groove in the back plate and inserting the driving element of the chip on film into the groove, the thickness of the display device can be reduced and damage to the driving element can be suppressed or prevented.

The effects of the embodiments of the present disclosure are not limited to the above-described examples, and a variety of other effects can be encompassed within the present disclosure.

A display device according to embodiments of the present disclosure can be described as follows.

A display device according to an embodiment of the present disclosure can include a display panel, a back plate disposed below the display panel, a printed circuit board disposed below the back plate and electrically connected to the display panel, a chip on film having a first side electrically connected to the display panel and a second side electrically connected to the printed circuit board, and a first adhesive layer including a first region disposed between the display panel and the back plate, a second region extending from the first region and bent to surround one end of the back plate, and a third region extending from the second region and disposed between the back plate and the printed circuit board and between the chip on film and the back plate.

According to another feature of the present disclosure, the chip on film can be bent at the one end of the back plate and another side of the chip on film can be disposed below the printed circuit board.

According to yet another feature of the present disclosure, the chip on film can include a flexible film having a printed circuit formed therein and a driving element mounted on the flexible film, and the first adhesive layer can include an opening corresponding to the driving element in the third region.

According to yet another feature of the present disclosure, the back plate can include a groove corresponding to the driving element.

According to yet another feature of the present disclosure, the driving element can be inserted into the opening and the groove.

According to yet another feature of the present disclosure, the back plate can be in direct contact with the first region of the first adhesive layer.

According to yet another feature of the present disclosure, the chip on film can be in direct contact with the third region of the first adhesive layer.

According to yet another feature of the present disclosure, the printed circuit board can be in direct contact with the third region of the first adhesive layer.

According to yet another feature of the present disclosure, the first adhesive layer can be formed of a pressure sensitive adhesive.

According to yet another feature of the present disclosure, a side surface of the third region of the first adhesive layer can be positioned inward relative to a side surface of the printed circuit board.

According to yet another feature of the present disclosure, the display device can further include a polarizing layer disposed on the display panel, a cover layer disposed on the polarizing layer, and a second adhesive layer disposed between the cover layer and the polarizing layer.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device, comprising:
a display panel;
a back plate disposed below the display panel;
a printed circuit board disposed below the back plate and electrically connected to the display panel;
a chip on film having a first side electrically connected to the display panel and a second side electrically connected to the printed circuit board; and
a first adhesive layer including a first region disposed between the display panel and the back plate, a second region extending from the first region and bent to surround one end of the back plate, and a third region extending from the second region and disposed between the back plate and the printed circuit board and between the chip on film and the back plate.

2. The display device of claim 1, wherein the chip on film is bent at the one end of the back plate and the second side of the chip on film is disposed below the printed circuit board.

3. The display device of claim 2, wherein the chip on film includes a flexible film having a printed circuit formed therein and a driving element mounted on the flexible film, and
wherein the first adhesive layer includes an opening corresponding to the driving element in the third region.

4. The display device of claim 3, wherein the back plate includes a groove corresponding to the driving element.

5. The display device of claim 4, wherein the driving element is inserted into the opening and the groove.

6. The display device of claim 1, wherein the back plate is in direct contact with the first region of the first adhesive layer.

7. The display device of claim 6, wherein the chip on film is in direct contact with the third region of the first adhesive layer.

8. The display device of claim 6, wherein the printed circuit board is in direct contact with the third region of the first adhesive layer.

9. The display device of claim 1, wherein the first adhesive layer is formed of a pressure sensitive adhesive.

10. The display device of claim 9, wherein the first adhesive layer is a double-sided adhesive.

11. The display device of claim 1, wherein a side surface of the third region of the first adhesive layer is positioned inward relative to a side surface of the printed circuit board.

12. The display device of claim 1, further comprising:
a polarizing layer disposed on the display panel;
a cover layer disposed on the polarizing layer; and
a second adhesive layer disposed between the cover layer and the polarizing layer.
